(19) United States
(12) Patent Application Publication
(10) Pub. No.: US 2021/0147712 A1
(43) Pub. Date: May 20, 2021

(54) POLISHING SLURRY AND METHOD OF MANUFACTURING SEMICONDUCTOR DEVICE

(71) Applicant: SAMSUNG ELECTRONICS CO., LTD., Suwon-si (KR)

(72) Inventors: Deuk Kyu Moon, Seoul (KR); Do Yoon KIM, Hwaseong-si (KR); Kenji TAKAI, Hwaseong-si (KR); Young Seok PARK, Yongin-si (KR); Moon Il JUNG, Suwon-si (KR)

(21) Appl. No.: 16/861,539

(22) Filed: Apr. 29, 2020

(30) Foreign Application Priority Data
Nov. 15, 2019 (KR) 10-2019-0147030

(51) Int. Cl. C09G 1/02; C09K 3/14; H01L 21/321

(52) U.S. Cl. CPC C09G 1/02; B82Y 30/00; H01L 21/3212; C09K 3/1409

(57) ABSTRACT

A polishing slurry including a fullerene derivative including a metal cation, a method of preparing the polishing slurry, and a method of manufacturing a semiconductor device using the polishing slurry.

### CROSS-REFERENCE TO RELATED APPLICATION

This application claims priority to Korean Patent Application No. 10-2019-0147030 filed in the Korean Intellectual Property Office on Nov. 15, 2019, and all the benefits accruing therefrom under 35 U.S.C. § 119, the content of which in its entirety is herein incorporated by reference.

### BACKGROUND

### 1. Field

A polishing slurry, a method of preparing the polishing slurry, and a method of manufacturing a semiconductor device are disclosed.

### 2. Description of the Related Art

Recently, according to the miniaturization of electronic devices and consequent miniaturization of integrated circuits, various methods of forming microstructures such as metal wires having a width of several nanometers or narrow trench isolation are of interest and have been studied.

In the forming of the microstructures, a polishing process may be performed to make a flat surface of the microstructures. One example of the polishing process is a chemical mechanical polishing (CMP). Chemical mechanical polishing is a process that includes providing polishing slurry including abrasives between a surface of a semiconductor substrate to be polished and a polishing pad and contacting the semiconductor substrate with the polishing pad to planarize a surface of the substrate.

### SUMMARY

Polishing slurries that include conventional abrasives with an average particle size in the tens of nanometers such as silica tend to form microstructures, and may cause damage and shape deformation of fine pitch structures in semiconductor structures.

An embodiment provides a polishing slurry capable of improving polishing performance while reducing damage and deformation of fine pitch structures.

Another embodiment provides a method of preparing the polishing slurry.

Another embodiment provides a method of manufacturing a semiconductor device using the polishing slurry.

According to an embodiment, a polishing slurry includes a fullerene derivative including a metal cation.

The metal cation may be a cation of at least one metal of Fe, Nb, Ni, Os, Pd, Ru, Ti, V, Su, Ag, Co, Cr, Cu, Mo, or Mn.

The metal cation may be Fe³⁺, Fe²⁺, Cu⁺, Cu²⁺, Cu³⁺, or a combination thereof.

The metal cation may be bound to the surface of the fullerene derivative by an ionic bond or a coordinating bond.

The fullerene derivative may have at least one negatively charged functional group.

The negatively charged functional group may include at least one of a hydroxy group, a carbonyl group, a carboxylate group, a sulfonate group, a sulfate group, a sulfhydryl group, or a phosphate group.

The fullerene derivative may be represented by Chemical Formula 1.

Cₓ(OH)_{y} Chemical Formula 1

wherein, x is 60, 70, 74, 76, or 78 and y is an integer from 8 to 50.

An average particle diameter of the fullerene derivative may be less than about 10 nm.

The fullerene derivative may be included in a polishing slurry in an amount of about 0.001 wt % to about 10 wt % based on a total weight of the polishing slurry.

The metal cation may be included in an amount of less than or equal to about 0.001 wt % based on a total weight of the polishing slurry.

The polishing slurry may further include an oxidizing agent, a chelating agent, a corrosion inhibitor, a surfactant, a dispersing agent, an acidity regulator, a solvent, or a combination thereof.

The polishing slurry may not include a metal-containing oxidation promoter.

According to another embodiment, a method of preparing a polishing slurry includes obtaining a fullerene derivative including a metal cation, and dispersing the fullerene derivative in a dispersion medium. The obtaining of the fullerene derivative may include synthesizing a fullerene derivative by adding a fullerene, an oxidizing agent, and a metal precursor to a solvent to prepare a mixed solution, and heat-treating the mixed solution.

The metal precursor may include at least one metal cation of Fe, Nb, Ni, Os, Pd, Ru, Ti, V, Su, Ag, Co, Cr, Cu, Mo, or Mn.

The heat-treating temperature may be about 40° C. to about 90° C. According to another embodiment, a method of manufacturing a semiconductor device includes positioning a semiconductor structure and a surface of a polishing pad so that they face each other; supplying the polishing slurry between the surface of the semiconductor structure and the polishing pad; and contacting the surface of the semiconductor structure with the polishing pad to polish the surface with the polishing slurry.

The polishing slurry may polish a metal wire in the semiconductor substrate.

The metal wire may include tungsten.

A ratio of a polishing rate of tungsten to an etching rate of tungsten may be greater than or equal to about 3.

Polishing performance may be improved while reducing damage and shape deformation of fine pitch structures of a semiconductor device.

### BRIEF DESCRIPTION OF THE DRAWINGS

FIGS. 1 to 4 are cross-sectional views showing a method of manufacturing a semiconductor device according to an embodiment.

FIG. 1 represents an insulation layer on a substrate with trenches formed in the insulation layer, and a conductive layer formed on the walls and floor of the trenches;

FIG. 2 represents a metal layer of an embodiment formed on the conductive layer and fills the trenches of FIG. 1;

FIG. 3 represents a metal structure of an embodiment that is planarized to coincide with a surface of the insulation layer; and

FIG. 4 represents a metal structure of an embodiment with a capping layer.

### DETAILED DESCRIPTION

Example embodiments will hereinafter be described in detail, and may be easily performed by a person having an ordinary skill in the related art. However, this disclosure may be embodied in many different forms and is not to be construed as limited to the example embodiments set forth herein. Rather, these embodiments are provided so that this disclosure will be thorough and complete, and will fully convey the scope of the invention to those skilled in the art.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” “third” etc. may be used herein to describe various compounds, components, regions, layers and/or sections, these compounds, components, regions, layers and/or sections should not be limited by these terms. These terms are only used to distinguish one compound, component, region, layer or section from another compound, component, region, layer, or section.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims. Hereinafter, a polishing slurry according to an embodiment is described.

The polishing slurry according to an embodiment may include a fullerene derivative including a metal cation.

The fullerene derivative may have a fullerene core and at least one functional group bound to the fullerene core. The fullerene core may generally be hydrophobic, and may be C60, C70, C74, C76, or C78, but is not limited thereto.

The functional group bound to the fullerene core may be for example negatively charged functional group, for example at least one of a hydroxy group, a carbonyl group, a carboxylate group, a sulfonate group, a sulfate group, a sulfhydryl group, or a phosphate group, but is not limited thereto. For example, the negatively charged functional group may be a hydroxy group. The term “negatively charged” refers to a functional group with a localized anionic charge, or a functional group with lone pairs on oxygen.

The fullerene derivative may be a fullerene with a hydrophilic functional group. The hydrophilic functional group may include for example at least one of a hydroxyl group, a carbonyl group, a carboxyl group, a sulfhydryl group, or a phosphate group, but is not limited thereto. For example, the hydrophilic functional group may be a hydroxyl group. The fullerene derivative may have one or more negatively charged functional groups in average, for example 1 to 50 negatively charged functional groups in average, 2 to 50 negatively charged functional groups in average, 3 to 50 negatively charged functional groups in average, 5 to 50 negatively charged functional groups in average, 8 to 50 negatively charged functional groups in average, 10 to 50 negatively charged functional groups in average, 12 to 50 negatively charged functional groups in average, 16 to 50 negatively charged functional groups in average, 20 to 50 negatively charged functional groups in average, 24 to 50 negatively charged functional groups in average, 28 to 50 negatively charged functional groups in average, for example 28 to 48 negatively charged functional groups in average, 28 to 46 negatively charged functional groups in average, 28 to 44 negatively charged functional groups in average, 28 to 42 negatively charged functional groups in average, 30 to 42 negatively charged functional groups in average, 30 to 40 negatively charged functional groups in average, or 32 to 38 negatively charged functional group in average, per the fullerene core.

The negatively charged functional groups bound to the fullerene core may further impart chemical polishing properties and reduce damage and morphological deformation, such as scratches, dishing, and/or erosion, to a structure of a semiconductor structure to be polished.

Herein, the average number of negatively charged functional groups of the negatively charged fullerene may be confirmed by elemental analysis, thermogravimetric analysis, spectroscopic analysis, mass spectrometry, and the like. For example, it may be an average value of the highest two peaks in the liquid chromatography mass spectrum (LC-MS).

The fullerene derivative includes a metal cation. The metal cation may be located on the surface of the fullerene derivative, and the metal cation may be for example attached via an ionic bond or a coordinating bond to the fullerene core and/or to the functional groups bound to the fullerene core.

The metal cation may be derived from a soluble metal compound including metal ion, wherein the metal ion may be at least one of, for example, a transition metal ion or a Group IIIA/IVA metal ion. For example, the metal cation may be a cation of a metal that is at least one of Fe, Nb, Ni, Os, Pd, Ru, Ti, V, Su, Ag, Co, Cr, Cu, Mo, or Mn and may be for example a cation of Fe or Cu, but is not limited thereto. For example, the metal cation may be monovalent, divalent, or trivalent ions, such as Fe³⁺, Fe²⁺, Cu⁺, Cu²⁺, Cu³⁺, a combination thereof. In an embodiment, it may be for example Fe³⁺, Fe²⁺, or a combination thereof, or in another embodiment, it may be for example Fe³⁺.

While not being bound by any theory, it may be understood that the metal cation included in the fullerene derivative attracts electrons produced during oxidation of the polished metal, and thus, can provide an electron withdrawing effect, which combined with the negatively charged functional groups of the fullerene derivative, may quickly passivate a surface of a polished metal.

The presence and content of metal cation may be confirmed by inductively coupled plasma atomic emission spectroscopy (ICP-AES).

For example, the fullerene derivative may be represented by Chemical Formula 1.

Cₓ(OH)_{y} Chemical Formula 1

wherein, x is 60, 70, 74, 76, or 78 and y is an integer from 8 to 50.

For example, y of Chemical Formula 1 may be an integer from 16 to 50, 20 to 50, or 20 to 44, or 20 to 40, or 28 to 40, or 28 to 36, or 32 to 36.

The fullerene derivative may effectively function as an abrasive in a polishing slurry. The fullerene derivative may have a relatively small width size, e.g., a diameter, of less than or equal to about 10 nanometers (nm) unlike a conventional abrasive such as silica having a particle diameter of tens to hundreds of nanometers. The fullerene derivative may be effectively applied to the fine pitch structures, e.g. a fine pitch structure of a semiconductor structure having a width of less than or equal to about 10 nm.

For example, the fullerene derivative may be a fine particle having an average particle diameter of less than about 10 nanometers (nm), within the range, less than about 8 nm, less than about 7 nm, less than about 5 nm, less than about 3 nm, less than about 2 nm, or less than about 1 nm, for example greater than or equal to about 0.01 nm and less than about 10 nm, greater than or equal to about 0.01 nm and less than about 8 nm, greater than or equal to about 0.01 nm and less than about 7 nm, greater than or equal to about 0.01 nm and less than about 5 nm, greater than or equal to about 0.01 nm and less than 3 nm, greater than or equal to about 0.01 nm and less than about 2 nm, or greater than or equal to about 0.01 nm and less than about 1 nm.

The fullerene derivative may be included in an amount of about 0.001 wt % to about 10 weight percent (wt %) based on a total amount of the polishing slurry (including a solvent). Within the range, the fullerene derivative may be included in an amount of about 0.001 wt % to about 8 wt %, about 0.001 wt % to about 5 wt %, about 0.001 wt % to about 3 wt %, about 0.001 wt % to about 2 wt %, about 0.001 wt % to about 1 wt %, about 0.001 wt % to about 0.8 wt %, or about 0.001 wt % to about 0.5 wt %.

The metal cation included in the fullerene derivative may be included in an amount of less than or equal to about 0.001 wt % based on a total amount of the polishing slurry (including a solvent), or within the range, the metal cation may be included in an amount of about 0.0001 wt % to about 0.001 wt %, about 0.0001 wt % to about 0.0008 wt %, about 0.0001 wt % to about 0.0006 wt %, about 0.0001 wt % to about 0.0005 wt %, about 0.0002 wt % to about 0.0005 wt %, or about 0.0002 wt % to about 0.0004 wt % based on a total amount of the polishing slurry (including a solvent).

The fullerene derivative including the metal cation in a polishing slurry may activate or facilitate an oxidation process of the polished metal. The process of applying the polishing slurry would include polishing of the polished metal, and chelating the polished metal to have greater oxidizing power compared with a fullerene derivative that does not include a metal cation.

The pH of the polishing slurry may be achieved or maintained by any suitable methods, considering any polishing rate, dispersion stability, and the like. For example, pH of the polishing slurry may be for example about 1.0 to about 7.0, within the range about 1.0 to about 5.0, about 1.0 to about 4.0, about 1.0 to about 3.0, about 1.0 to about 2.5, about 1.2 to about 2.5, about 1.5 to about 2.5, about 1.5 to about 2.0, or about 1.5 to about 1.8.

The polishing slurry may further include an additive and the additive may include for example an oxidizing agent, a chelating agent, a corrosion inhibitor, a surfactant, a dispersing agent, an acidity regulator, a solvent, or a combination thereof, but is not limited thereto.

The oxidizing agent may be added to the polishing composition during or immediately before the polishing process, such as a hydrogen peroxide solution, periodic acid, potassium iodide, potassium permanganate, ammonium sulfate, ammonium molybdate, nitric acid, potassium nitrate, sodium hydroxide, potassium hydroxide, or a combination thereof, but is not limited thereto.

The oxidizing agent may be included in an amount of about 0.1 wt % to about 10 wt % based on a total amount of the polishing slurry (including a solvent). Within the range, the oxidizing agent may be included in an amount of about 0.1 wt % to about 8 wt %, about 0.1 wt % to about 6 wt %, about 0.1 wt % to about 4 wt %, about 0.1 wt % to about 3 wt %, about 0.1 wt % to about 2 wt %, or about 0.1 wt % to about 1 wt %.

The chelating agent may be, for example, phosphoric acid, nitric acid, citric acid, malonic acid, salts thereof, or a combination thereof, but is not limited thereto.

The chelating agent may be included in an amount of about 0.002 wt % to about 20 wt % based on a total amount of the polishing slurry (including a solvent). Within the range, the chelating agent may be included in an amount of about 0.002 wt % to about 10 wt %, about 0.002 wt % to about 5 wt %, about 0.002 wt % to about 1 wt %, about 0.002 wt % to about 0.5 wt %, about 0.002 wt % to about 0.1 wt %, about 0.002 wt % to about 0.07 wt %, about 0.002 wt % to about 0.04 wt %, or about 0.002 wt % to about 0.02 wt %.

The corrosion inhibitor may act as a polishing controlling agent that delays a chemical reaction of the oxidizing agent to suppress corrosion in low step areas where physical polishing does not occur, and that is removed by physical actions of abrasive particles in the high step areas where polishing takes place, thereby enabling polishing. For example, compounds including cyclic nitrogen compounds and derivatives thereof are more effective, and compounds including benzoquinone, benzyl butyl phthalate, benzyl-dioxolane, or the like may be used. In an embodiment, 1,2,3-triazole, 1,2,4-triazole, or an isomeric mixture of 2,2′-[[(5-methyl-1H-benzotriazole-1-yl)-methyl]imino]bis-ethanol may be specifically applied, but is not limited thereto.

The corrosion inhibitors may be included in an amount of about 0.001 wt % to about 10 wt %, specifically about 0.001 wt % to about 5 wt %, and more specifically about 0.001 wt % to about 3 wt %, based on the total weight of the polishing slurry. The amount of corrosion inhibitor will depend upon considering corrosion inhibitory effects, polishing rates, and dispersion stability of the slurry composition, and surface properties of the polished material.

The surfactant may be an ionic or non-ionic surfactant, and may be, for example, a copolymer of ethylene oxide, a copolymer of propylene oxide, an amine compound, or a combination thereof, but is not limited thereto.

The dispersing agent may promote dispersion of the carbon abrasive particles, and may include, for example, a water-soluble monomer, a water-soluble oligomer, a water-soluble polymer, a metal salt, or a combination thereof. A weight average molecular weight of the water-soluble polymer may be less than or equal to about 10,000 grams per mole (g/mol), for example, less than or equal to about 5,000 g/mol, or less than or equal to about 3,000 g/mol. The metal salt may be for example a copper salt, a nickel salt, a cobalt salt, a manganese salt, a tantalum salt, a ruthenium salt, or a combination thereof. The dispersing agent may include, for example, poly(meth)acrylic acid, poly(meth)acryl maleic acid, polyacrylonitrile-co-butadiene-acrylic acid, carboxylic acid, sulfonic ester, sulfonic acid, phosphoric ester, cellulose, diol, a salt thereof, or a combination thereof, but is not limited thereto.

The acidity regulator may adjust the pH of the polishing slurry, and may be, for example, an inorganic acid, an organic acid, salts thereof, or a combination thereof. The inorganic acids may include, for example, nitric acid, hydrochloric acid, phosphoric acid, sulfuric acid, hydrofluoric acid, bromic acid, iodic acid, or a salt thereof, and the organic acid may be, for example, formic acid, malonic acid, maleic acid, oxalic acid, adipic acid, citric acid, acetic acid, propionic acid, fumaric acid, lactic acid, salicylic acid, benzoic acid, succinic acid, phthalic acid, butyric acid, glycolic acid, lactic acid, tartaric acid, or a salt thereof, but are not limited thereto.

Each additive may be included independently, for example, in a trace amount of about 1 part per million (ppm) to about 100,000 ppm, but is not limited thereto.

The polishing slurry may further include a solvent capable of dissolving or dispersing the aforementioned components. The solvent may be a polar solvent, for example, and may be water, alcohol, acetic acid, acetone, or a mixture thereof. In one example, the solvent may be water, for example distilled water, deionized water, ion exchanged water and/or ultrapure water.

The polishing slurry may not include a metal-containing oxidation promoter. Since the metal cation included in the fullerene derivative is capable of activating or facilitating the oxidation process of the polished metal (e.g., tungsten) by the oxidizing agent, the polishing slurry may not include a metal-containing oxidation promoter. As a result of the reduction in the metal content as compared with the polishing slurry including a separate metal-containing oxidation promoter, it is possible to reduce contamination in the polishing process due to excess metal cations and side reactions with the polished metal. For example, the polishing slurry may not include iron nitrate (Fe(NO₃)₃) as a metal-containing oxidation promoter, and iron (e.g., Fe³⁺) cations included in the fullerene derivative may effectively activate an oxidation process of the polished metal by hydrogen peroxide to improve the material removal rate (MRR) of the polished metal.

The polishing slurry may be used for polishing or planarizing various semiconductor structures, for example, the polishing slurry may be applied in a polishing process of a conductor such as a metal wire or a polishing process of an insulator such as an insulation layer or a shallow trench isolation (STI). For example, the polishing slurry may be used to polish a conductive layer, an insulating layer, and/or a semiconductor layer having a charged surface in a semiconductor substrate. The polishing slurry may be used effectively to polish a conductive layer, an insulating layer, and a semiconductor layer which generally have negatively-charged surfaces.

For example, the polishing slurry may be used to polish a conductor such as a metal wire in a semiconductor substrate and may be used to polish a conductor such as copper (Cu), tungsten (W), or an alloy thereof.

Hereinafter, an example of a method of preparing the aforementioned polishing slurry is described.

The method of preparing the polishing slurry according to an embodiment includes obtaining a fullerene derivative including a metal cation and dispersing the fullerene derivative in a dispersion medium. The step of obtaining may include synthesizing the fuller derivative with the metal cation. The synthesizing of the fullerene derivative with a metal cation may include adding a fullerene, an oxidizing agent, and a metal precursor to a solvent to prepare a mixed solution, and heat-treating the mixed solution.

In an exemplary embodiment, a mixed solvent of an organic solvent and water is prepared in one vessel. The organic solvent may be, for example, toluene, benzene, dimethylformamide, tetrahydrofuran, dimethyl sulfoxide, 1-methylnaphthalene, 1,2,4-trimethylbenzene, p-xylene or a combination thereof, and the water may be for example distilled water and/or deionized water. The organic solvent and water may be mixed in a volume ratio of about 10:90 to about 90:10, for example about 20:80 to about 80:20, about 30:70 to about 70:30, about 40:60 to about 60:40, or about 50:50. Since the organic solvent and water have different polarity, there may be some phase separation, i.e., some separation into an organic phase composed of an organic solvent and an aqueous phase composed of water.

Subsequently, the fullerene, the metal precursor, and the oxidizing agent are added to the mixed solvent. The fullerene, the metal precursor, and the oxidizing agent may be added simultaneously, or the fullerene may be added first and dispersed therein and then the metal precursor and the oxidizing agent may be added.

The fullerene may be, for example, C60, C70, C74, C76 or C78, but is not limited thereto.

The metal precursor may be a soluble metal compound including a metal cation, wherein the metal cation may be at least one of, for example, a transition metal ion or a Group IIIA/IVA metal ion, such as Fe, Nb, Ni, Os, Pd, Ru, for example at least one selected from Ti, V, Su, Ag, Co, Cr, Cu, Mo, or Mn, but are not limited thereto. The soluble metal compounds may include, for example, citrate, oxalate, acetate, tartrate, nitriloacetic acid, ethylenediaminetetraacetic acid, phosphonic acid, phosphonic acid, glycolic acid, lactic acid, malic acid, tartaric acid, α-hydroxycarboxylic acid, hydroxyamino acid, or combination thereof, but are not limited thereto.

The oxidizing agent may be, for example, hydrogen peroxide, sodium hydroxide, potassium hydroxide, or a combination thereof, but is not limited thereto.

The metal precursor may be included in an amount of about 10 parts by weight to about 500 parts by weight based on 100 parts by weight of fullerene. The oxidizing agent may be included in an amount of about 500 parts by weight to about 3,000 parts by weight based on 100 parts by weight of fullerene.

The fullerene may be dispersed in the organic phase, and low-valence fullerene derivatives may be formed by hydrophilic groups such as a few hydroxyl groups present in the organic phase. The low-valence fullerene derivatives herein refer to fullerenes having a low number of hydrophilic groups, for example fullerenes having from about 2 to 10 hydrophilic groups, such as Cₓ(OH)_{y} wherein x is 60, 70, 74, 76, or 78 and y is an integer from 2 to 10.

Subsequently, the aforementioned mixture is heat-treated. The heat-treating may be for example heating the mixture to a temperature of about 40° C. to about 90° C., for about 12 hours to about 132 hours, for example about 50° C. to about 90° C., about 50° C. to about 80° C., or about 60° C. to about 80° C. By heat-treating, the low-valence fullerene derivative may move into the aqueous phase, and the low-valence fullerene derivative in the aqueous phase may react with the oxidizing agent such as hydrogen peroxide to form a high-valence fullerene derivative. Herein, the high-valence fullerene derivative refers to a fullerene having a high number of hydrophilic groups, and may be, for example, a fullerene having about 16 to 40 hydrophilic groups, for example, Cₓ(OH)_{y} (where x is 60, 70, 74, 76, or 78 and y is an integer from 16 to 40). The metal precursor may dissociate in an aqueous phase to form a metal cation, and the metal cation may effectively shorten a formation time of the high-valence fullerene derivative. Although not intending to be bound by a specific theory, the carbon-carbon double bond and the metal cation of fullerene may form an intermediate of carbon-metal cation-carbon, thereby lowering activation energy of the reaction of introducing hydroxyl groups into the fullerene. The high-valence fullerene derivative may exist in an anionic state in the aqueous phase and may be combined with metal cations resulting from the metal precursor to form a fullerene derivative including a metal cation.

The fullerene derivative including the metal cation may be dispersed in an aqueous phase, that is, water, and the organic solvent which is an organic phase may be removed after formation of the fullerene derivative including the metal cation.

As described above, the fullerene derivative may significantly shorten the reaction time by including the metal cation in the synthesis step. For example, a time required to synthesize the fullerene derivative including the metal cation may be about two times shorter than a time required to synthesize the fullerene derivative without the metal cation. For example, the time required for synthesizing the fullerene hydroxide is about 6 to 14 days, whereas the time for synthesizing the fullerene hydroxide including the metal cation may be, for example, within about 80 hours or about 75 hours.

The fullerene derivative including the metal cation may be dispersed in the dispersion medium so that the fullerene derivative may be uniformly dispersed in the polishing slurry. The dispersion medium may be water or an organic solvent, and the organic solvent may be methyl alcohol (MeOH), ethyl alcohol (EtOH), propyl alcohol (PA), isopropyl alcohol (IPA), butanol (BA), ethylene glycol (EG), 1,2-dichlorobenzene, dimethylformamide (DMF), dimethylacetamide (DMAc), methyl ethyl ketone (MEK), methyl isobutyl ketone (MIBK), butyl cellosolve (BC), butyl cellosolve acetate (BCA), n-methyl-2-pyrrolidone (NMP), ethyl acetate (EA), butyl acetate (BA), acetone, cyclohexanone, toluene, or a combination thereof, but if the dispersion medium may disperse a composite of the fullerene derivative and the metal cation, it is not limited thereto.

The polishing slurry may be prepared by optionally adding various additives to the water in which the fullerene derivative including the metal cation is dispersed.

The aforementioned polishing slurry may be applied when forming various semiconductor structures, and may be applied, for example, to a polishing process of a conductor such as metal wire, or a polishing process of an insulator such as shallow trench isolation (STI) or an insulating film.

Hereinafter, an example of a method of manufacturing a semiconductor device using the aforementioned polishing slurry is described.

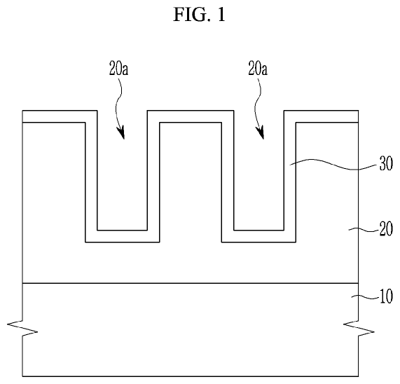

FIGS. 1 to 4 are cross-sectional views showing a method of manufacturing a semiconductor device according to an embodiment.

Referring to FIG. 1, an interlayer insulating layer 20 is formed on the semiconductor substrate 10. The interlayer insulating layer 20 may include an oxide, a nitride, and/or an oxynitride. Subsequently, the interlayer insulating layer 20 is etched to provide a trench 20a. The trench 20a may have a width of less than or equal to about 10 nm. Subsequently, a barrier layer 30 is formed on the wall surface of the trench. The barrier layer 30 may include, for example, Ta and/or TaN, but is not limited thereto.

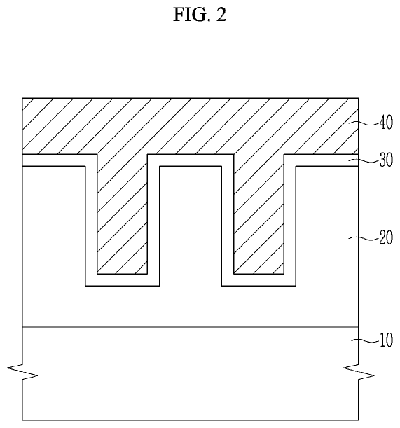

Referring to FIG. 2, a metal such as tungsten (W) or copper (Cu) is filled in the inside of the trench to provide a metal layer 40.

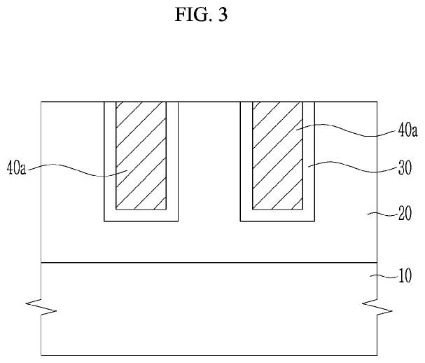

Referring to FIG. 3, a surface of the metal layer 40 is planarized to match the surface of the interlayer insulating layer 20 and forms a filled metal layer 40a. The planarization may be performed by chemical mechanical polishing using a chemical mechanical polishing (CMP) equipment, and may use the above-described polishing slurry, which will be described later. For example, if the barrier layer 30 is a Ta layer and the metal layer 40 is a Cu layer, the polishing selectivity of Ta to Cu of the polishing slurry is relatively high, for example, the polishing selectivity of Ta to Cu is greater than about 50:1.

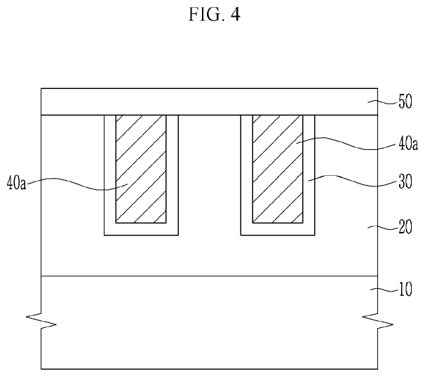

Referring to FIG. 4, a capping layer 50 is formed on the filled metal layer 40 and the interlayer insulating layer 20. The capping layer 50 may include SiN and/or SiC but is not limited thereto.

Hereinafter, a method of planarization for forming the filled metal layer 40a is described. The planarization may be performed by chemical mechanical polishing using chemical mechanical polishing (CMP) equipment and the polishing slurry described. The chemical mechanical polishing equipment may include for example a lower base; a platen rotatable on the lower base; a polishing pad disposed on the platen; a pad conditioner; and at least one polishing slurry supplying equipment disposed adjacent to the polishing pad and supplying the polishing pad with the polishing slurry.

The platen may be rotated on a surface of the lower base. For example, the platen may be supplied with a rotation power from a motor disposed in the lower base. Accordingly, the platen may be rotated with a center of an imaginary rotating axis perpendicular to the surface of the platen. The imaginary rotating axis may be perpendicular to the surface of the lower base.

The platen may be equipped with at least one supply line through which liquid is injected and discharged. Water may be injected and discharged through the supply line inside the platen to adjust a temperature of the platen. For example, cooling water may be injected and discharged through the supply line inside the platen and thus lower the temperature of the platen. For example, hot water at a high temperature may be injected and discharged through the supply line inside the platen and thus raise the temperature of the platen.

The polishing pad may be disposed on the surface of the platen so that it may be supported by the platen. The polishing pad may be rotated together with the platen. The polishing pad may have a rough polishing surface. This polishing surface may directly contact a surface of the semiconductor structure and thus mechanically polish a surface of the semiconductor device. The polishing pad may be a porous material having a plurality of micropores which may hold the polishing slurry.

The pad conditioner may be disposed adjacent to the polishing pad and maintain a polishing surface so that the surface of the semiconductor substrate 10 may be effectively polished.

The polishing slurry supplying equipment may be disposed adjacent to the polishing pad to supply the polishing pad with the polishing slurry. The polishing slurry supplying equipment may include a nozzle to supply the polishing slurry on the polishing pad, and a voltage supplying unit to apply a predetermined voltage to the nozzle. The polishing slurry in the nozzle is charged by a voltage applied by the voltage supplying unit, which is then discharged toward the polishing pad. The polishing slurry supplying equipment may supply the aforementioned polishing slurry.

The chemical mechanical polishing may be for example performed by positioning the semiconductor structure with substrate 10 and a surface that faces a polishing pad, supplying the polishing slurry, which is stored in the polishing slurry supplying equipment, between the semiconductor structure surface and the polishing pad, and contacting the surface of the semiconductor structure with the polishing pad to polish the surface with the polishing slurry.

For example, the polishing slurry may be used to polish a conductor such as a metal wire in a semiconductor structure and may be used to polish a conductor such as copper (Cu), tungsten (W), or an alloy thereof, but is not limited thereto.

For example, the supplying of the polishing slurry may be for example at a rate of about 10 milliliters per minute (ml/min) to about 100 ml/min, for example at a flow rate of about 2 microliters to about 10 microliters.

The polishing may be performed by contacting a surface of the semiconductor structure with the polishing pad and rotating them to produce a mechanical friction. For example, a pressure of about 1 pound per square inch (psi) to about 5 psi may be applied during the polishing step.

For example, if the metal layer 40 and the filled metal layer 40a include tungsten, a ratio of the material removal rate (MRR) of tungsten relative to the etching rate (ER) of tungsten by the polishing slurry may be relatively high. The ratio of material removal rate (MRR) of tungsten relative to the etching rate (ER) may be for example greater than or equal to about 1, greater than or equal to about 2, greater than or equal to about 3, greater than or equal to about 4, greater than or equal to about 5, greater than or equal to about 6, greater than or equal to about 7, greater than or equal to about 8, greater than or equal to about 9, greater than or equal to about 10, greater than or equal to about 12, greater than or equal to about 14, greater than or equal to about 16, greater than or equal to about 18, or greater than or equal to about 20, or within a range, about 1 to about 25, about 2 to about 20, about 3 to about 20, about 3 to about 15, about 3 to about 12, about 3 to about 10, about 3 to about 9, about 3 to about 8, about 3 to about 7, about 4 to about 7, or about 5 to about 7.

Due to the aforementioned ratio of the polishing rate relative to the etching rate, the etching rate of the metal wire may be reduced, ensuring the flatness of the semiconductor line structure following the polishing process, as well as minimizing the undesired recesses in the line structure.

Hereinafter, the embodiments are illustrated in more detail with reference to examples. However, these examples are exemplary, and the scope of claims is not limited thereto.

### SYNTHESIS EXAMPLES OF FULLERENE DERIVATIVE

### Synthesis Example 1

6 grams (g) of fullerenol (C₆₀(OH)₁₀, Frontier Carbon Corp.), 600 milliliters (ml) of a 30 weight percent (wt %) hydrogen peroxide solution (Fuji Film Wako Pure Chemical Industries, Ltd.), and 0.0003 wt % of Fe(NO₃)₃ are added to a 2,000 ml flask, and the fullerenol mixture is heat-treated at 70° C. for 8 hours. Subsequently, 1 Liter (L) of isopropyl alcohol, 800 ml of ethyl acetate, and 1 L of hexane are sequentially added thereto to extract brown precipitates. The precipitates are separated by using a centrifuge, and washed and dried under a reduced pressure to obtain a fullerene derivative represented by C₆₀(OH)₁₆.16(H₂O). The number of hydroxyl groups of the fullerene derivative is determined by conducting an elemental analysis with regard to a structure of the fullerene derivative (Automatic Elemental Analyzer 2400 II, Perkin Elmer) to measure carbon (C), hydrogen (H), and oxygen (O) contents in the compound and in addition, a thermogravimetric analysis (TGA) to measure a moisture content (degree of hydration) of the fullerene derivative.

### Synthesis Example 2

A fullerene derivative represented by C₆₀(OH)₂₈.14(H₂O) is obtained according to the same method as in Synthesis Example 1 except that the heat treatment time of the fullerenol dispersion is increased to 12 hours.

### Synthesis Example 3

A fullerene derivative represented by C₆₀(OH)₃₂.9(H₂O) is obtained according to the same method as in Synthesis Example 1 except that the heat treatment time of the fullerenol dispersion is increased to 16 hours.

### Synthesis Example 4

A fullerene derivative represented by C₆₀(OH)₃₆.8(H₂O) is obtained according to the same method as in Synthesis Example 1 except that the heat treatment time of the fullerenol dispersion is increased to 22 hours.

### Synthesis Example 5

A fullerene derivative represented by C₆₀(OH)₄₀.9(H₂O) is obtained according to the same method as Synthesis Example 1 except that the heat treatment time of the fullerenol dispersion is increased to 30 hours.

### Synthesis Example 6

A fullerene derivative is synthesized in the same method as in Synthesis Example 4 except that 0.0002 wt % of Fe(NO₃)₃ is used.

### Synthesis Example 7

A fullerene derivative is synthesized in the same method as in Synthesis Example 4 except that 0.0005 wt % of Fe(NO₃)₃ is used.

### Comparative Synthesis Examples 1 to 5

Comparative fullerene derivatives are synthesized according to the methods as in Examples 1 to 5 with respect to the respective fullerene used in each of Examples 1 to 5, however the comparative fullerenes are each prepared with extended times of heat-treatment as reported in Table 1. Moreover, the comparative fullerenes are prepared without using (i.e., in the absence of) Fe(NO₃)₃. The extended heat times for each comparative example is needed to obtain similar (or same) degrees of hydroxylation of the fullerene in the absence of Fe(NO₃)₃.

### Evaluation I

Heat treatment time taken to obtain fullerene derivatives having the same number of hydroxyl group in Synthesis Examples and Comparative Synthesis Examples is evaluated.

The results are shown in Table 1.

TABLE 1

| | | Synthesis time |
|---|---|---|
| | Fullerene derivative | (hour) |
| Synthesis Example 1 | C₆₀(OH)₁₆•16(H₂O) | 8 |
| Comparative Synthesis Example 1 | C₆₀(OH)₁₆•16(H₂O) | 24 |
| Synthesis Example 2 | C₆₀(OH)₂₈•14(H₂O) | 12 |
| Comparative Synthesis Example 2 | C₆₀(OH)₂₈•14(H₂O) | 72 |
| Synthesis Example 3 | C₆₀(OH)₃₂•9(H₂O) | 16 |
| Comparative Synthesis Example 3 | C₆₀(OH)₃₂•9(H₂O) | 96 |
| Synthesis Examples 4, 6, 7 | C₆₀(OH)₃₆•8(H₂O) | 22 |
| Comparative Synthesis Example 4 | C₆₀(OH)₃₆•8(H₂O) | 144 |
| Synthesis Example 5 | C₆₀(OH)₄₀•9(H₂O) | 30 |
| Comparative Synthesis Example 5 | C₆₀(OH)₄₀•9(H₂O) | 192 |

Referring to Table 1, as a result of comparing synthesis examples with comparative synthesis examples, synthesis times taken of the fullerene derivatives having the same number of hydroxyl group in synthesis examples are greatly shortened compared with comparative synthesis examples.

### PREPARATION EXAMPLES OF POLISHING SLURRY

### Preparation Example 1

0.1 wt % of the fullerene derivative according to Synthesis Example 1, 0.06 wt % of benzotriazole, 0.4 wt % of ammonium dihydrogen phosphate, 0.5 wt % of tris-ammonium citrate, and 1.6 wt % of a 30 wt % hydrogen peroxide solution (H₂O₂) are mixed with a balance of water to prepare polishing slurry.

### Preparation Examples 2 to 7

Polishing slurries are prepared according to the same method as in Preparation Example 1 except that the fullerene derivatives of Synthesis Examples 2 to 7 are respectively used instead of the fullerene derivative of Synthesis Example 1.

### Comparative Preparation Example 1

Polishing slurry is prepared according to the same method as in Preparation Example 1 except that the fullerene derivative of Comparative Synthesis Example 1 is used, and 0.0003 wt % of Fe(NO₃)₃ is added to the comparative slurry.

### Comparative Preparation Examples 2 to 5

Polishing slurries are prepared according to the same method as in Preparation Example 1 except that each fullerene derivative of Comparative Synthesis Example 2 to 5, respectively, are used, and 0.0003 wt % of Fe(NO₃)₃ is added to each of the comparative slurries.

### Evaluation II

The contents of Fe in the polishing slurries according to the preparation examples are evaluated.

The contents of Fe are measured using an atomic absorption spectrometer (AA-6300, Shimadzu Corporation), (ICP-AES: Inductively coupled plasma atomic emission spectroscopy). The results are shown in Table 2.

TABLE 2

| | ICP-AES |
|---|---|
| | Fe (wt %) |
| Preparation Example 1 | 0.00028 |
| Preparation Example 2 | 0.00028 |
| Preparation Example 3 | 0.00028 |
| Preparation Example 4 | 0.00028 |
| Preparation Example 5 | 0.00028 |
| Preparation Example 6 | 0.00019 |
| Preparation Example 7 | 0.00047 |

Referring to Table 2, the polishing slurries of preparation examples include a trace amount of Fe.

### Evaluation III

Material removal rates (MRR) and etching rates (ER) are evaluated by performing polishing under the following conditions.

Polishing equipment: MA-200e (Musashino Denshi Corp.)

Polished Object:

(1) Wafer for measuring polishing rate: A 20 mm by 20 mm wafer having a 1.5 m-thick tungsten (W) film formed on a silicon substrate is prepared.

(2) Specimen for measuring etching rate: A 20 mm×20 mm pattern specimen is prepared. This specimen is composed of a tungsten line having a width of 0.20 (micrometers) μm and a silicon oxide spacer line having a width of 0.20 μm between the tungsten lines.

(3) Polishing pad: 101000 (Dow Chemical Company)

(4) The rotation number of polishing platen: 90 revolutions per minute (rpm)

(5) The rotation number of polishing pad: 90 rpm

(6) A method of supplying polishing liquid: 200 ml of polishing slurry is put on the polishing pad and polishing is performed.

(7) Polishing pressure: 14 kilopascals (kPa)

(8) Polishing temperature: 25° C.

The MRR is calculated by performing polishing for 2 minutes. An electrical resistance measurement is used to determine the thickness of the tungsten (W) film before and after the polishing using methods well known to those of ordinary skill in the art. The thickness values are then converted into a polishing rate. The ER is determined by measuring the changed weight of the specimen before and after the polishing, and then converting the weight measurements into an etching amount of tungsten.

The results are shown in Table 3

TABLE 3

| | Polishing rate | Etching rate | Polishing ratio |
|---|---|---|---|
| | (Å/min) | (Å/min) | (polish/etch) |
| Preparation Example 1 | 148 | 45 | 3.29 |
| Comparative Preparation | 102 | 47 | 2.18 |
| Example 1 | | | |
| Preparation Example 2 | 219 | 52 | 4.22 |
| Comparative Preparation | 132 | 58 | 2.27 |
| Example 2 | | | |
| Preparation Example 3 | 234 | 48 | 4.87 |
| Comparative Preparation | 150 | 57 | 2.64 |
| Example 3 | | | |
| Preparation Example 4 | 231 | 37 | 6.24 |
| Preparation Example 6 | 225 | 38 | 5.84 |
| Preparation Example 7 | 240 | 55 | 4.36 |
| Comparative Preparation | 167 | 55 | 3.04 |
| Example 4 | | | |
| Preparation Example 5 | 170 | 55 | 3.09 |
| Comparative Preparation | 125 | 54 | 2.31 |
| Example 5 | | | |

Referring to Table 3, when the polishing slurries of the preparation examples are used to polish a tungsten (W) film, a ratio of a polishing rate relative to an etching rate is relatively high if compared with a respective polishing slurry of a Comparative preparation example. Accordingly, in accordance with an embodiment, if the polishing slurries of preparation examples are used to polish a tungsten film, polishing performance may be improved, and/or damage or shape deformation of fine pitch structure of a semiconductor device may be reduced.

While this disclosure has been described in connection with what is presently considered to be practical example embodiments, it is to be understood that the invention is not limited to the disclosed embodiments, but, on the contrary, is intended to cover various modifications and equivalent arrangements included within the spirit and scope of the appended claims.

### DESCRIPTION OF SYMBOLS

10: semiconductor substrate
20: interlayer insulating layer
20a: trench
30: barrier layer
40: metal layer
40a: filled metal layer
50: capping layer

What is claimed is:

1. A polishing slurry, comprising a fullerene derivative comprising a metal cation.

2. The polishing slurry of claim 1, wherein the metal cation is a cation of at least one of Fe, Nb, Ni, Os, Pd, Ru, Ti, V, Su, Ag, Co, Cr, Cu, Mo, or Mn.

3. The polishing slurry of claim 1, wherein the metal cation is Fe³⁺, Fe²⁺, Cu⁺, Cu²⁺, Cu³⁺, or a combination thereof.

4. The polishing slurry of claim 1, wherein the metal cation is bound to the surface of the fullerene derivative by an ionic bond or a coordinating bond.

5. The polishing slurry of claim 1, wherein the fullerene derivative has at least one negatively charged functional group.

6. The polishing slurry of claim 5, wherein the negatively charged functional group comprises at least one of a hydroxy group, a carbonyl group, a carboxylate group, a sulfonate group, a sulfate group, a sulfhydryl group, or a phosphate group.

7. The polishing slurry of claim 1, wherein the fullerene derivative is represented by Chemical Formula 1:
Cₓ(OH)_{y} Chemical Formula 1
wherein, x is 60, 70, 74, 76, or 78 and y is an integer from 8 to 50.

8. The polishing slurry of claim 1, wherein an average particle diameter of the fullerene derivative is less than about 10 nanometers.

9. The polishing slurry of claim 1, wherein the fullerene derivative is included in an amount of about 0.001 weight percent to about 10 weight percent, based on a total weight of the polishing slurry.

10. The polishing slurry of claim 1, wherein the metal cation is included in an amount of less than or equal to about 0.001 weight percent based on a total weight of the polishing slurry.

11. The polishing slurry of claim 1, wherein the polishing slurry further comprises an oxidizing agent, a chelating agent, a corrosion inhibitor, a surfactant, a dispersing agent, an acidity regulator, a solvent, or a combination thereof.

12. The polishing slurry of claim 11, wherein the polishing slurry does not contain a metal-containing oxidation promoter.

13. A method of preparing a polishing slurry, comprising obtaining a fullerene derivative including a metal cation, and dispersing the fullerene derivative in a dispersion medium, wherein the obtaining of the fullerene derivative includes a synthesis of the fullerene derivative, the synthesis comprising
adding a fullerene, an oxidizing agent, and a metal precursor to a solvent to prepare a mixed solution, and
heat-treating the mixed solution.

14. The method of claim 13, wherein the metal precursor comprises at least one metal cation of Fe, Nb, Ni, Os, Pd, Ru, Ti, V, Su, Ag, Co, Cr, Cu, Mo, or Mn.

15. The method of claim 13, wherein the heat-treating of the mixed solution includes a temperature about 40° C. to about 90° C.

16. A method of manufacturing a semiconductor device, the method comprising
positioning a semiconductor structure having a surface, wherein the surface and a polishing pad face each other;
supplying the polishing slurry of claim 1 between the surface of the semiconductor structure and the polishing pad; and
contacting the surface of the semiconductor structure with the polishing pad to polish the surface with the polishing slurry.

17. The method of claim 16, wherein the semiconductor structure comprises a metal wire that is polished.

18. The method of claim 17, wherein the metal wire comprises tungsten.

19. The method of claim 18, wherein a ratio of a polishing rate of tungsten to an etching rate of tungsten is greater than or equal to about 3.
